(19) United States
(12) Patent Application Publication
(10) Pub. No.: US 2024/0379754 A1
(43) Pub. Date: Nov. 14, 2024

(54) SEMICONDUCTOR DEVICES AND METHODS FOR MANUFACTURING

(71) Applicant: Taiwan Semiconductor Manufacturing Company, Ltd., Hsinchu (TW)

(72) Inventors: Tzu-Ging Lin, Kaohsiung City (TW); Shun-Hui Yang, Taoyuan County (TW); Chen Yen Ju, Hsinchu (TW); Yun-Chen Wu, Hsinchu (TW); Chun-Liang Lai, Hsinchu City (TW)

(73) Assignee: Taiwan Semiconductor Manufacturing Company, Ltd., Hsinchu (TW)

(21) Appl. No.: 18/315,684

(22) Filed: May 11, 2023

(51) Int. Cl. H01L 29/06; H01L 21/3065; H01L 29/423; H01L 29/66; H01L 29/775; H01L 29/786

(52) U.S. Cl. CPC H01L 29/0673; H01L 21/3065; H01L 29/42392; H01L 29/66439; H01L 29/66545; H01L 29/775; H01L 29/78696

(57) ABSTRACT

Devices with metal structures formed with seams and methods of fabrication are provided. An exemplary method includes forming a metal plug having a top surface formed with a seam; depositing a film over the top surface of the metal plug and at least partially filling the seam; and etching the film from over the metal plug, wherein the film remains in the seam.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIG. 2 illustrates a top-down view of a gate-all-around (GAA) semiconductor device, according to some embodiments.

FIGS. 3-12 are cross-sectional views of a device during successive stages of fabrication of the method of FIG. 1, in accordance with some embodiments.

FIGS. 13-16 are cross-sectional views of the device focused on the fin to be removed, before and after removal, in accordance with some embodiments.

FIG. 17 is a cross-sectional view of a fin adjacent to a removed fin, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of a insulation structure, such as a Continuous Poly On Diffusion Edge (CPODE) structure, that divides a fin in two. In certain embodiments, a portion of a selected fin structure is removed and replaced with insulation material.

In embodiments herein, a CPODE-last processing method, i.e., after metal gate formation, enable high overlay tolerance by self-aligning structures. Further, CPODE-last processing methods provide for lower epitaxial layer stress, particularly when compared to COPDE-first processing which suffers epitaxial stress release during the etch process.

Embodiments of the present disclosure offer advantages over the existing art, though it is understood that other embodiments may offer different advantages, not all advantages are necessarily discussed herein, and no particular advantage is required for all embodiments.

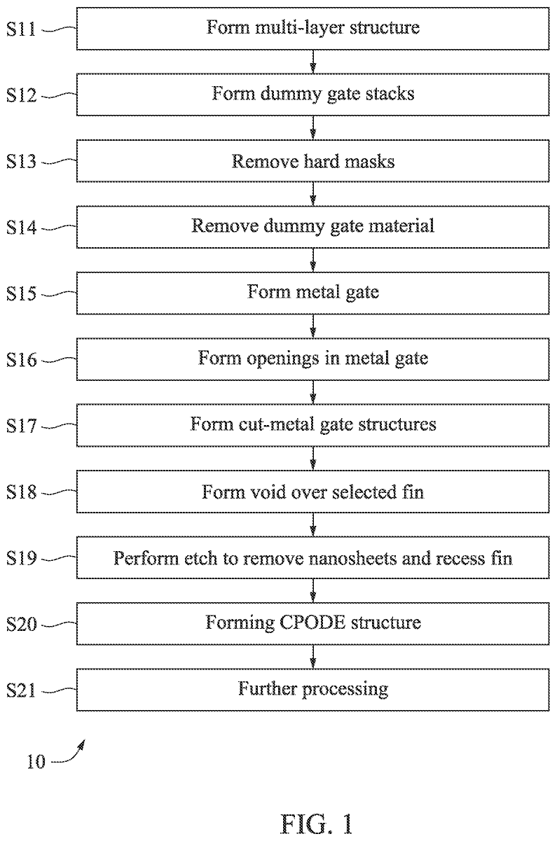

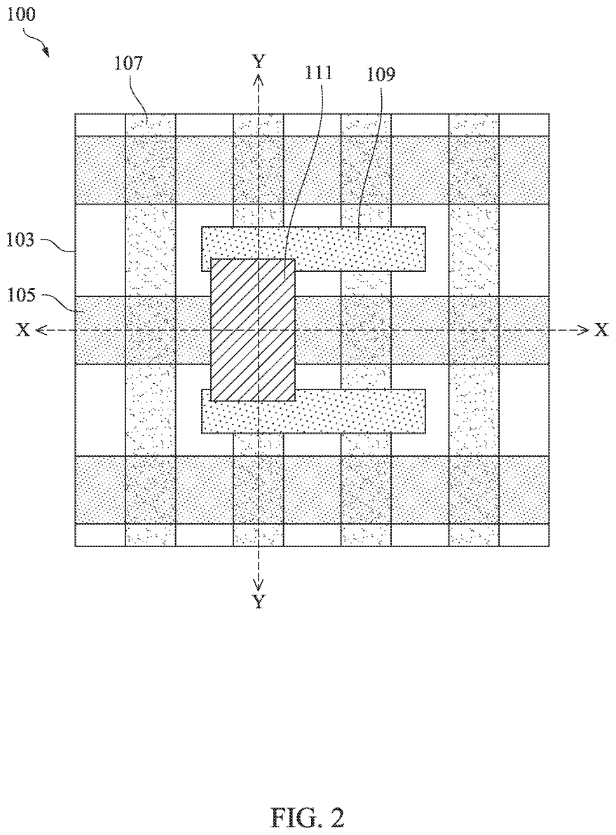

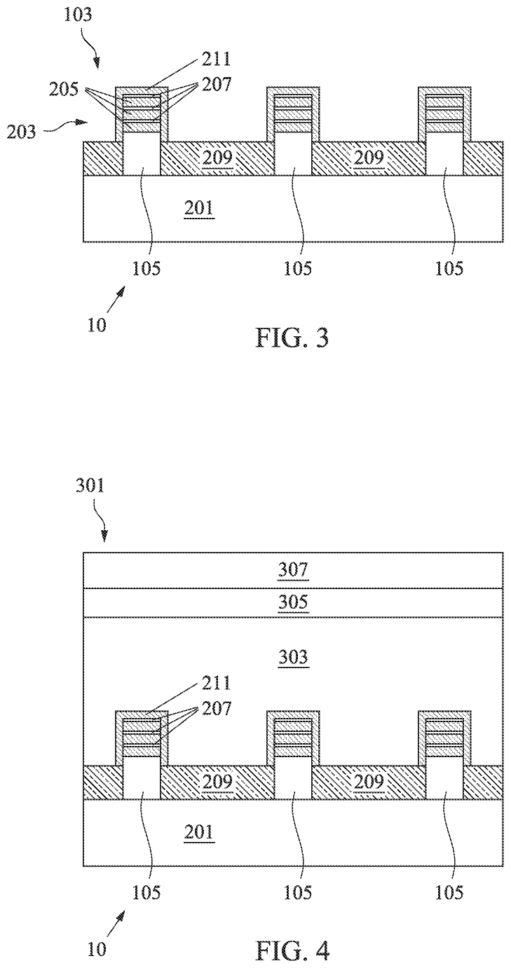

For purposes of the discussion that follows, FIG. 1 provides a flow chart for a method 10 for fabricating a semiconductor device 100 during a semiconductor fabrication process. Method 10 is described below with reference to FIGS. 2-12 which illustrate the semiconductor device 100 at various stages of fabrication according to method 10. FIG. 2 illustrates a top-down view of an intermediate structure in forming a device 100, such as a gate-all-around (GAA) semiconductor device, according to some embodiments. FIGS. 3-12 are cross-sectional views in which the vertical direction is defined by the Z-axis and the lateral direction is defined by the Y-axis. It is understood that method 10 includes steps having features of a complementary metal-oxide-semiconductor (CMOS) technology process flow and thus, are only described briefly herein. Also, additional steps may be performed before, after, and/or during method 10.

In FIG. 2, the device 100 includes a multi-layer structure 103 comprising a plurality of nanosheets formed over a semiconductor substrate 201 (illustrated in the following figures), fins 105 formed in the multi-layer structure 103, and a plurality of gate electrodes 107 over the fins 105. FIG. 2 further illustrates a plurality of cut-metal gate structures 109 separating two of the gate electrodes 107 and a Continuous Poly On Diffusion Edge (CPODE) structure 111 dividing one of the fins 105 in two and intersecting the cut-metal gate structures 109.

Although three fins 105 are illustrated in FIG. 2 and in the following figures, it is understood that depending on the desired design and number of the GAA semiconductor devices 100, any suitable number of fins 105 may be formed in the multi-layer structure 103 to form the desired GAA semiconductor devices 100. Furthermore, any suitable number of gate electrodes 107, CPODE structures 111, and cut-metal gate structures 109 may be formed to form the desired GAA semiconductor devices 100.

In FIG. 2, the X-axis extends through the length of the fin 105 and passes through the CPODE structure 111. Further, the Y-axis extends through the length of a gate electrode 107 that has been separated by the two cut-metal gate structures 109, through the two cut-metal gate structures 109, and through the CPODE structure 111 intersecting the two cut-metal gate structures 109. The following cross-sectional views are taken along the Y-axis.

Referring now to FIGS. 1 and 3, a method 10 for fabricating a semiconductor device 100 includes, at S11, forming a multi-layer structure 103 over a semiconductor material, such as a substrate, and forming fin structures 105 in the multi-layer structure 103, in accordance with some embodiments.

In an embodiment the substrate 201 is a semiconductor substrate, which may be, for example, a silicon substrate, a silicon germanium substrate, a germanium substrate, a III-V material substrate (e.g., GaAs, GaP, GaAsP, AlInAs, AlGaAs, GaInAs, InAs, GaInP, InP, InSb, and/or GaInAsP; or a combination thereof), or a substrate formed of other semiconductor materials with, for example, high band-to-band tunneling (BTBT). The substrate 201 may be doped or un-doped. In some embodiments, the substrate 201 may be a bulk semiconductor substrate, such as a bulk silicon substrate that is a wafer, a semiconductor-on-insulator (SOI) substrate, a multi-layered or gradient substrate, or the like.

FIG. 3 illustrates a deposition process to form the multi-layer structure 103 in an intermediate stage of manufacturing the GAA semiconductor device 100, according to some embodiments. In particular, FIG. 3 further illustrates a series of depositions that are performed to form a multi-layer stack 203 of alternating materials of first layers 205 and second layers 207 over the substrate 201.

According to some embodiments, the first layers 205 may be formed using a first semiconductor material with a first lattice constant, such as SiGe, Ge, Si, GaAs, InSb, GaSb, InAlAs, InGaAs, GaSbP, GaAsSb, combinations of these, or the like. In some embodiments, a first layer 205 of the first semiconductor material (e.g., SiGe) is epitaxially grown on the substrate 201 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer CVD (ALCVD), ultrahigh vacuum CVD (UHVCVD), reduced pressure CVD (RPCVD), a combination thereof, or the like, may also be utilized. In some embodiments, the first layer 205 is formed to thicknesses of from about 3 nm and about 10 nm. However, any suitable thickness may be utilized while remaining within the scope of the embodiments.

After the first layer 205 has been formed over the substrate 201, a second layer 207 may be formed over the first layer 205. According to some embodiments, the second layers 207 may be formed using a second semiconductor material such as Si, SiGe, Ge, GaAs, InSb, GaSb, InAlAs, InGaAs, GaSbP, GaAsSb, combinations of these, or the like with a second lattice constant that is different from the first lattice constant of the first layer 205. In a particular embodiment in which the first layer 205 is silicon germanium, the second layer 207 is a material such as silicon. However, any suitable combination of materials may be utilized for the first layers 205 and the second layers 207.

In some embodiments, the second layer 207 is epitaxially grown on the first layer 205 using a deposition technique similar to that used to form the first layer 205. However, the second layer 207 may use any of the deposition techniques suitable for forming the first layer 205, as set forth above or any other suitable technique. According to some embodiments, the second layer 207 is formed to a similar thickness to that of the first layer 205. However, the second layer 207 may also be formed to a thickness that is different from the first layer 205. According to some embodiments, the second layer 207 may be formed to a thickness of from about 5 nm and about 15 nm. However, any suitable thickness may be used.

After forming the second layer 207 over the first layer 205, the deposition process is repeated to form the remaining material layers in the series of alternating materials of the first layers 205 and the second layers 207 until a desired topmost layer of the multi-layer stack 203 has been formed. According to the present embodiment, the first layers 205 may be formed to a same or similar first thickness and the second layers 207 may be formed to the same or similar second thickness. However, the first layers 205 may have different thicknesses from one another and/or the second layers 207 may have different thicknesses from one another and any combination of thicknesses may be used for the first layers 205 and the second layers 207. According to the present embodiment, the topmost layer of the multi-layer stack 203 is formed as a second layer 207; however, in other embodiments, the topmost layer of the multi-layer stack 203 may be formed as a first layer 205. Additionally, although embodiments are disclosed herein comprising three of the first layers 205 and three of the second layers 207, the multi-layer stack 203 may have any suitable number of layers (e.g., nanosheets). For example, the multi-layer stack 203 may comprise from two to ten nanosheets. In some embodiments, the multi-layer stack 203 may comprise equal numbers of the first layers 205 to the second layers 207; however, in other embodiments, the number of the first layers 205 may be different from the number of the second layers 207. According to some embodiments, the multi-layer stack 203 may be formed to a height of from about 12 nm to about 100 nm. However, any suitable height may be used.

FIG. 3 further illustrates, a patterning process of the multi-layer structure 103 and a formation of isolation regions 209 in an intermediate stage of manufacturing the GAA semiconductor device 100, in accordance with some embodiments. The patterning process is used to form fins 105 in the multi-layer structure 103 and to form trenches between the fins 105 in preparation for forming the isolation regions 209. The patterning process for forming the fins 105, according to some embodiments, comprises applying a photoresist over the multi-layer stack 203 and then patterning and developing the photoresist to form a mask over the multi-layer stack 203. After being formed, the mask is then used during an etching process, such as an anisotropic etching process to transfer the pattern of the mask into the underlying layers to form the trenches through the multi-layer stack 203 and into the substrate 201 to define the fins 105, wherein the fins 105 are separated by the trenches.

Additionally, while a single mask process has been described, this is intended to be illustrative and is not intended to be limiting, as the gate all around (GAA) device structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In an exemplary embodiment, the isolation regions 209 are formed as shallow trench isolation regions by depositing a dielectric material in the trenches. According to some embodiments, the dielectric material used to form the isolation regions 209 may be a material such as an oxide material (e.g., a flowable oxide), high-density plasma (HDP) oxide, or the like. The dielectric material may be formed, after an optional cleaning and lining of the trenches, using either a chemical vapor deposition (CVD) method (e.g., the HARP process), a high density plasma CVD method, or other suitable method of formation to fill or overfill the regions around the fins 105. In some embodiments, a post placement anneal process (e.g., oxide densification) is performed to densify the material of the isolation regions 209 and to reduce its wet etch rate. A chemical mechanical polishing (CMP), an etch, a combination of these, or the like may be performed to remove any excess material of the isolation regions 209.

After the dielectric material has been deposited to fill or overfill the regions around the fins 105, the dielectric material may then be recessed away from the surface of the fins 105 to form the isolation regions 209. The recessing may be performed to expose at least a portion of the sidewalls of the fins 105 adjacent to the top surface of the fins 105. The dielectric material may be recessed using a wet etch by dipping the top surface of the fins 105 into an etchant selective to the material of the dielectric material, although other methods, such as a reactive ion etch, a dry etch, chemical oxide removal, or dry chemical clean may be used.

FIG. 3 further illustrates the formation of a dummy gate dielectric 211 over the exposed portions of the fins 105. After the isolation regions 209 have been formed, the dummy gate dielectric 211 may be formed by thermal oxidation, chemical vapor deposition, sputtering, or any other methods known and used in the art for forming a gate dielectric. Depending on the technique of gate dielectric formation, the dummy gate dielectric 211 thickness on the top may be different from the dummy dielectric thickness on the sidewall. In some embodiments, the dummy gate dielectric 211 may be formed by depositing a material such as silicon and then oxidizing or nitridizing the silicon layer in order to form a dielectric such as the silicon dioxide or silicon oxynitride. In such embodiments, the dummy gate dielectric 211 may be formed to a thickness of from about 3 Å to about 100 Å, such as about 10 Å. In other embodiments, the dummy gate dielectric 211 may also be formed from a high permittivity (high-k) material such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of from about 0.5 Å to about 100 Å, such as about 10 Å or less. Additionally, any combination of silicon dioxide, silicon oxynitride, and/or high-k materials may also be used for the dummy gate dielectric 211.

Cross-referencing FIGS. 1 and 4, method 10 may continue, at S12, forming sacrificial or dummy gate stacks 301 over the fins 105, in accordance with some embodiments. According to some embodiments, the dummy gate stacks 301 comprise a dummy gate dielectric 211, a dummy gate electrode 303 over the dummy gate dielectric 211, a first hard mask 305 over the dummy gate electrode 303, and a second hard mask 307 over the first hard mask 305.

In some embodiments, the dummy gate electrode 303 comprises a conductive material and may be selected from a group comprising of polysilicon, W, Al, Cu, AlCu, W. Ti, TiAlN, TaC, TaCN, TaSiN, Mn, Zr, TiN, Ta, TaN, Co, Ni, combinations of these, or the like. The dummy gate electrode 303 may be deposited by chemical vapor deposition (CVD), sputter deposition, or other techniques known and used in the art for depositing conductive materials. The thickness of the dummy gate electrode 303 may be from about 5 Å to about 500 Å. The top surface of the dummy gate electrode 303 may have a non-planar top surface, and may be planarized prior to patterning of the dummy gate electrode 303 or gate etch. Ions may or may not be introduced into the dummy gate electrode 303 at this point. Ions may be introduced, for example, by ion implantation techniques.

After the dummy gate electrode 303 has been formed, the dummy gate dielectric 211 and the dummy gate electrode 303 may be patterned. In an embodiment the patterning may be performed by initially forming a first hard mask 305 over the dummy gate electrode 303 and forming the second hard mask 307 over the first hard mask 305.

According to some embodiments, the first hard mask 305 comprises a dielectric material such as silicon nitride (SiN), oxide (OX), silicon oxide (SiO), titanium nitride (TiN), silicon oxynitride (SiON), combinations of these, or the like. The first hard mask 305 may be formed using a process such as chemical vapor deposition, plasma enhanced chemical vapor deposition, atomic layer deposition, or the like. However, any other suitable material and method of formation may be utilized. The first hard mask 305 may be formed to a thickness of from about 20 Å to about 3000 Å, such as about 20 Å.

The second hard mask 307 comprises a separate dielectric material from the material of the first hard mask 305. The second hard mask 307 may comprise any of the materials and use any of the processes suitable for forming the first hard mask 305 and may be formed to a same or similar thickness as the first hard mask 305. In embodiments where the first hard mask 305 comprises silicon nitride (SiN), the second hard mask 307 may be e.g., an oxide (OX). However, any suitable dielectric materials, processes and thicknesses may be used to form the second hard mask.

After the first hard mask 305 and the second hard mask 307 have been formed, the first hard mask 305 and the second hard mask 307 may be patterned. Patterning of the first hard mask 305 and second hard mask 307 occurs in the X-dimension, i.e., distanced into or out of the drawing sheet for the cross-sectional views of FIGS. 3-12. Thereafter, various processes may be performed to form desired structures, etching of the dummy gate material to form distinct dummy gate stacks, formation of spacers, etching of openings for source/drain regions, epitaxial growth of source/drain regions, implant processes, and other typical gate processing.

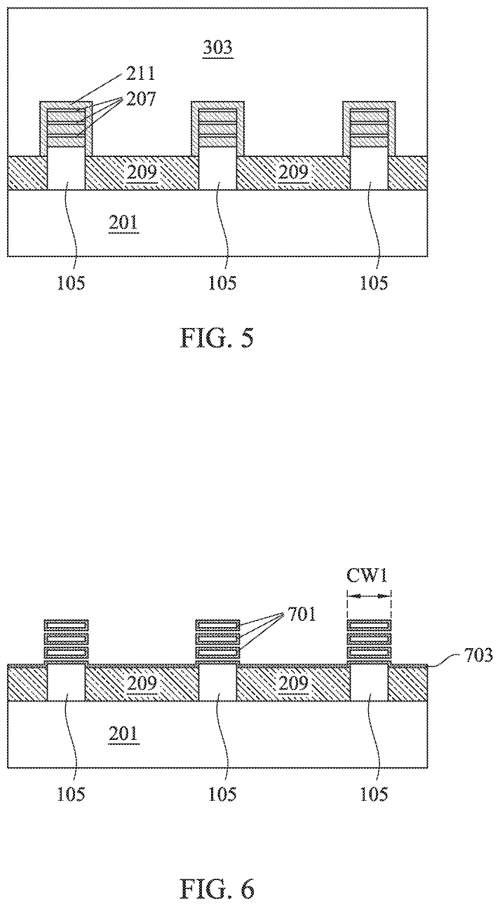

Cross-referencing FIGS. 1 and 5, method 10 may continue, at S13, with removal of the first hard mask 305 and the second hard mask 307. According to some embodiments, one or more etching processes and/or the chemical mechanical planarization (CMP) may be utilized to remove the first hard mask 305 and the second hard mask 307. As such, the dummy gate electrode 303 is exposed after the removal of the first hard mask 305.

Cross-referencing FIGS. 1 and 6, method 10 may continue, at S14, with removing the dummy gate electrode 303 and the dummy gate dielectric 211. FIG. 6 further illustrates a wire-release process to form nanostructures 701, i.e., vertically-spaced nanosheets, from the second layers 207, in accordance with some embodiments. FIG. 6 further illustrate the formation of a gate dielectric 703 over the nanostructures 701, according to some embodiments.

After being exposed by removal of the first hard mask 305, the dummy gate electrode 303 may be removed in order to expose the underlying dummy gate dielectric 211. In an embodiment the dummy gate electrode 303 is removed using, e.g., one or more wet or dry etching process that utilizes etchants that are selective to the material of the dummy gate electrode 303. However, any suitable removal process may be utilized.

After the dummy gate dielectric 211 has been exposed by removal of the dummy gate electrode 303, the dummy gate dielectric 211 may be removed. In an embodiment the dummy gate dielectric 211 may be removed using, e.g., a wet etching process, although any suitable etching process may be utilized.

After the dummy gate dielectric 211 has been removed (which also exposes the sides of the first layers 205), the first layers 205 may be removed from between the substrate 201 and from between the second layers 207 in a wire release process step. The wire release process step may also be referred to as a sheet release process step, a sheet formation process step, a nanosheet formation process step or a wire formation process step. In an embodiment the first layers 205 may be removed using a wet etching process that selectively removes the material of the first layers 205 (e.g., silicon germanium (SiGe)) without significantly removing the material of the substrate 201 and the material of the second layers 207 (e.g., silicon (Si)). However, any suitable removal process may be utilized.

For example, in an embodiment, an etchant such as a high temperature HCl may be used to selectively remove the material of the first layers 205 (e.g., SiGe) without substantively removing the material of the substrate 201 and/or the material of the second layers 207 (e.g., Si). Additionally, the wet etching process may be performed at a temperature of from 400° C. to about 600° C., such as about 560° C., and for a time of from about 100 seconds to about 600 seconds, such as about 300 seconds. However, any suitable etchant, process parameters, and time can be utilized.

By removing the material of the first layers 205, the sides of the second layers 207 (relabeled nanostructures 701 in FIG. 6) are exposed. According to some embodiments, the nanostructures 701 are vertically separated or spaced from one another by a spacing of from about 5 nm to about 15 nm, such as about 10 nm. The nanostructures 701 comprise the channel regions between opposite ones of the source/drain regions 503 and have a channel length (in the X-direction into and out of the drawing sheet) of from about 5 nm to about 180 nm, such as about 10 nm, and a channel width CW1, in the Y-direction, of from about 8 nm to about 100 nm, such as about 30 nm. In an embodiment the nanostructures 701 are formed to have the same thicknesses as the original thicknesses of the second layers 207 such as from about 3 nm to about 15 nm, such as about 8 nm, although the etching processes may also be utilized to reduce the thicknesses.

In some embodiments, the wire release step may include an optional step for the partial removal of the material of the second layers 207 (e.g., by over etching) during removal of the first layers 205. As such, the thicknesses of the nanostructures 701 are formed to have reduced thicknesses as compared to the original thickness of the second layers 207. As such, the nanostructures 701 may have thicknesses that are less than the thicknesses of the original second layers 207.

Although FIG. 6 illustrates the formation of three of the nanostructures 701, any suitable number of the nanostructures 701 may be formed from the nanosheets provided in the multi-layer stack 203. For example, the multi-layer stack 203 may be formed to include any suitable number of the first layers 205 and any suitable number of the second layers 207. As such, a multi-layer stack 203 comprising fewer first layers 205 and fewer second layers 207, after removal of the first layers 205, forms one or two of the nanostructures 701. Whereas, a multi-layer stack 203 comprising many of the first layers 205 and many of the second layers 207, after removal of the first layers 205, forms four or more of the nanostructures 701.

FIG. 6 further illustrates the formation of the gate dielectric 703 over the nanostructures 701, according to some embodiments. In an embodiment the gate dielectric 703 comprises a high-k material (e.g., K greater than or equal to 9) such as Ta₂O₅, Al₂O₃, Hf oxides, Ta oxides, Ti oxides, Zr oxides, Al oxides, La oxides (e.g., HfO₂, HfSiO, HfSiON, HfTaO, HfTiO, HfZrO, LaO, ZrO, TiO), combinations of these, or the like, deposited through a process such as atomic layer deposition, chemical vapor deposition, or the like. In some embodiments, the gate dielectric 703 comprises a nitrogen doped oxide dielectric that is initially formed prior to forming a metal content high-K (e.g., K value>13) dielectric material. The gate dielectric 703 may be deposited to a thickness of from about 1 nm to about 3 nm, although any suitable material and thickness may be utilized. In exemplary embodiments, the gate dielectric 703 wraps around the nanostructures 701, thus forming channel regions between the source/drain regions.

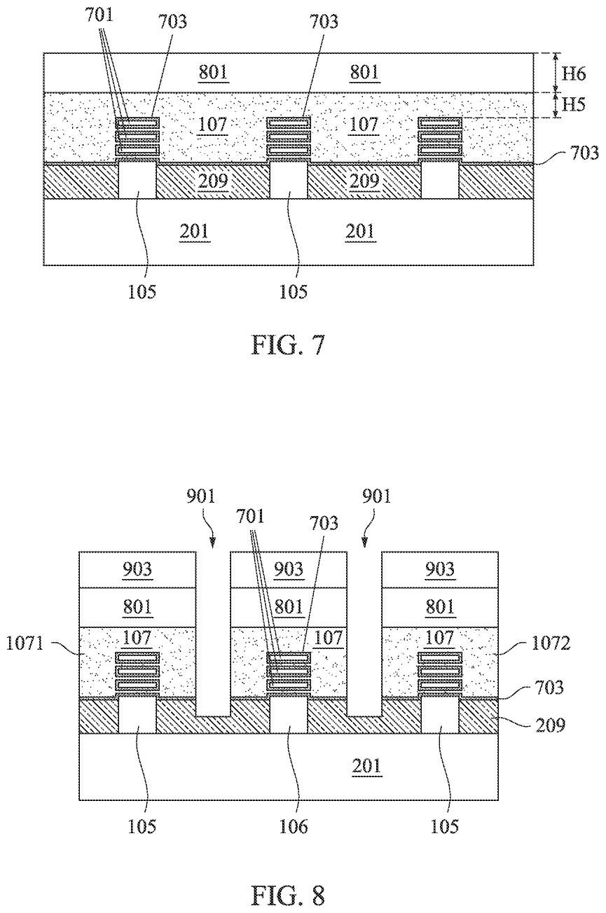

Cross-referencing FIGS. 1 and 7, method 10 may continue, at S15, with forming a metal gate over the fin structures. For example, method 10 includes forming gate electrodes 107 and gate caps 801, in accordance with some embodiments. After the gate dielectric 703 has been formed, the gate electrodes 107 are formed to surround the nanostructures 701. For example, inter-sheet portions of the metal gate are located between the nanosheets 701.

In some embodiments, the gate electrodes 107 are formed using multiple layers, each layer deposited sequentially adjacent to each other using a highly conformal deposition process such as atomic layer deposition, although any suitable deposition process may be utilized. According to some embodiments, the gate electrodes 107 may comprise a capping layer, a barrier layer, an n-metal work function layer, a p-metal work function layer, and a fill material.

The capping layer may be formed adjacent to the gate dielectric 703 and may be formed from a metallic material such as TaN, Ti, TiAlN, TiAl, Pt, TaC, TaCN, TaSiN, Mn, Zr. TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W. Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings left behind by the removal of the dummy gate electrode 303 have been filled, the materials of the gate electrode 107 and the gate dielectric 703 may be planarized in order to remove any material that is outside of the openings left behind by the removal of the dummy gate electrode 303. In a particular embodiment the removal may be performed using a planarization process such as chemical mechanical polishing, although any suitable planarization and removal process may be utilized. According to some embodiments, the gate electrodes may be formed to a length of from about 8 nm to about 30 nm. However, any suitable length may be used.

After being formed, the gate electrodes 107 may be recessed. According to some embodiments, the gate electrodes 107 may be recessed using an etching process such as a wet etch, a dry etch, combinations, or the like. After being recessed, the height of the gate electrodes 107 above a topmost one of the nanostructure 701 is a height H5, such as from about 8 nm to about 30 nm. However, any suitable height may be used.

The gate caps 801 may be formed by initially depositing a dielectric material over the gate electrodes 107 to fill and/or overfill the recesses. In some embodiments, the gate caps 801 are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps 801 are formed using a metal oxide of materials such as zirconium (Zr), hafnium (Hf), aluminum (Al), or the like. Furthermore, the gate caps 801 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps 801 may be planarized using a planarization process such as a chemical mechanical polishing process. After being planarized, the gate caps 801 have a sixth height H6 of from about 10 nm to about 30 nm. However, any suitable height may be used.

Cross-referencing FIGS. 1 and 8, method 10 may continue, at S16, with forming openings 901 in a cut-metal gate process, in accordance with some embodiments. After the gate caps 801 have been planarized, a masking layer 903 may be deposited over the planar surfaces of the gate caps 801. After being deposited, the masking layer 903 is patterned to expose the underlying materials including the gate caps 801 in desired locations of the cut-metal gate structures 109 that are to be formed.

After being patterned, the masking layer 903 is used as an etching mask to etch the underlying materials to form the openings 901 (e.g., trenches, recesses, channels or the like). In the etching process, the materials of the gate caps 801 and the gate electrodes 107 are etched using an anisotropic etching process. In exemplary embodiments, the etch process continues through the gate dielectric 703 and into the isolation regions 209. The openings 901 may be formed between adjacent fins 105 and may be formed to cut through one or more gate electrodes 107. According to some embodiments, two of the openings 901 are formed to cut through two adjacent gate electrodes 107 and are located on opposite sides of one of the fins 105, e.g., a selected fin 106, as shown in FIG. 1. After the openings 901 have been formed, the masking layer 903 is removed.

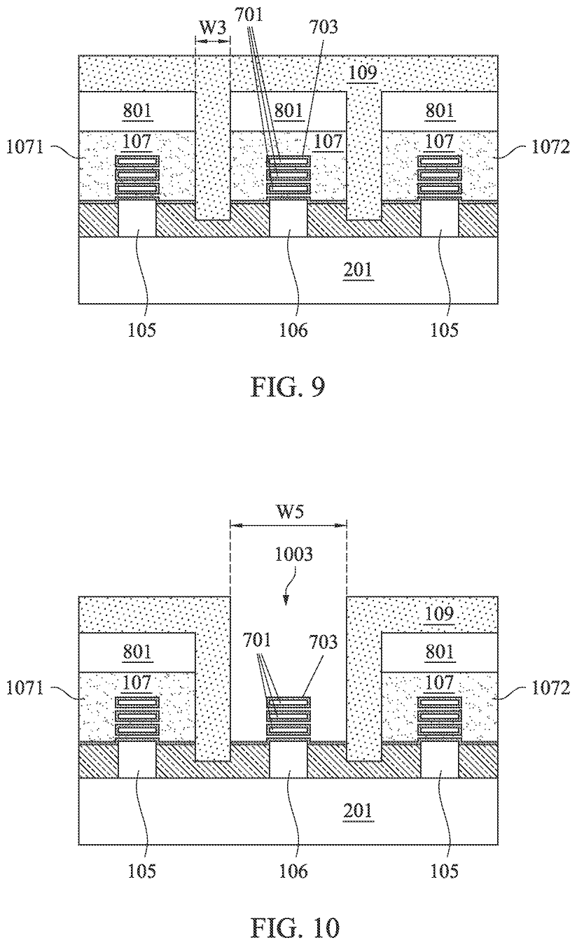

Cross-referencing FIGS. 1 and 9, method 10 may continue, at S17, with forming cut-metal gate structures 109, in accordance with some embodiments. After the openings 901 have been formed, the cut-metal gate structures 109 are formed by initially depositing a dielectric material to fill and overfill the openings 901. In accordance with some embodiments, the cut-metal gate structures 109 are formed using any dielectric material and deposition process suitable for forming the gate caps 801. In some embodiments, the dielectric material used to form the cut-metal gate structures 109 is the same as the dielectric material used to form the gate caps 801, although the dielectric materials may be different. For example, in embodiments where the gate caps 801 are formed using silicon nitride (SiN), the cut-metal gate structures 109 may also be formed using silicon nitride (SiN) in a deposition process such as Atomic Layer Deposition (ALD). However, any suitable dielectric materials and deposition processes may be used. According to some embodiments, the cut-metal gate structures 109 are formed to a width W3 of from about 5 nm to about 50 nm, such as about 10 nm. However, any suitable widths may be used.

The cut-metal gate structures 109 divide the two gate electrodes 107, which are relatively long, into a plurality of segmented gate electrodes 107 which are relatively short and isolate the segmented gate electrodes 107 from one another. Furthermore, the excess dielectric material of the cut-metal gate structures 109 outside of the openings 901 may be retained and used as a masking layer in the Continuous Poly On Diffusion Edge (CPODE) process.

Cross-referencing FIGS. 1 and 10, method 10 may continue, at S18, with forming a void or opening 1003 in an initial step of forming a Continuous Poly On Diffusion Edge (CPODE) structure 111, in accordance with some embodiments. The CPODE structure 111 may also be referred to herein as an isolation structure, a cut-poly structure or a cut-PODE structure and is discussed in greater detail with the following figures. In exemplary embodiments, forming the opening 1003 includes selectively removing the section of the metal gate 107 lying over the selected fin structure 106. For example, the process may remove all of the metal gate 107 between the dielectric regions 109.

After the cut-metal gate structures 109 have been formed, a photo resist may be formed over the excess dielectric material and openings may be formed in the photo resist in a desired location of the CPODE structure 111 to be formed. The opening in the photo resist is formed to reveal a portion of the gate cap 801 between the two cut-metal gate structures 109. Furthermore, edge portions of the cut-metal gate structures 109 may also be exposed through the openings in the photo resist in order to provide some process margin for the CPODE structure 111. According to some embodiments, the width of the exposed edge portions may be a width substantially equal to width W5. However, any suitable width may be used.

The photo resist is then used as an etching mask to etch the excess dielectric material 109, the gate cap 801, the gate electrode 107, and, optionally, edge portions of the cut-metal gate structures 109 so that the opening 1003 (e.g., trenches, recesses, channels or the like) is formed in the desired location of the CPODE structure 111. According to some embodiments, the etching process may stop on the gate dielectric 703. As a result, the gate dielectric 703 and the nanostructures 701 remain at the bottom of the opening 1003. According to some embodiments, the etching process used to form the opening 1003 may be an isotropic etching process (e.g., a wet etching process) using etchants that stop on the gate dielectric 703. However, other suitable etching process including anisotropic etching processes (e.g., a dry etching processes or reactive ion etching (RIE) processes), combinations of isotropic and anisotropic etches, or the like may also be used. According to some embodiments, the opening 1003 is formed to a width of from about 20 nm to about 200 nm, such as about 70 nm. However, any suitable width may be used.

After the gate dielectric 703 has been exposed by forming the opening 1003, another etching process is performed to remove the materials of the gate dielectric 703 within the opening 1003 and to expose the nanostructures 701, the fin 106, and isolation regions 209 within the opening 1003. According to some embodiments, a wet etch, a dry etch, combinations, or the like may be used to remove the material of the gate dielectric 703. However, any suitable etching process may be used.

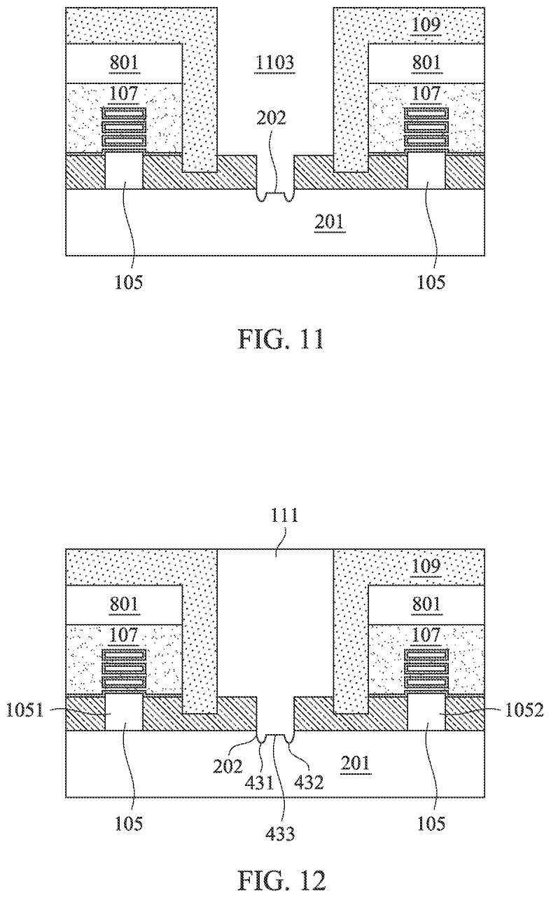

Cross-referencing FIGS. 1 and 11, method 10 may continue, at S19, with an intermediate step of performing the CPODE process including removing the nanostructures 701 and recessing the selected fin 106 to form opening 1103.

After exposing the nanostructures 701 and a portion of the fin 106 protruding above the isolation regions 209, a further etching process may be used to remove the materials of the nanostructures 701 and to recess the fin 106. In exemplary embodiments, the fin 106 is removed, and a portion of the underlying substrate 201 is etched. As a result, an upper surface of the substrate 201 is recessed to a recessed surface 202.

In exemplary embodiments, the etch process is a plasma etch.

After the nanostructures 701 have been removed and the portion of the fin 105 protruding above the isolation regions 209 has been recessed, the photo resist may be removed, for example, via an ashing process.

Cross-referencing FIGS. 1 and 12, method 10 may continue, at S20, with completing the CPODE process by forming the CPODE structure. For example, an insulator material or dielectric material may be deposited to fill and/or overfill the opening 1003. The CPODE structure 111 or insulation region 111 may be formed using a dielectric material such as a silicon nitride (SiN), oxide (OX), silicon oxynitride (SiON), silicon oxycarbonitride (SiOCN), silicon carbonitride (SiCN), or the like. According to some embodiments, the CPODE structure 111 is formed using a metal oxide of materials such as zirconium (Zr), hafnium (Hf), aluminum (Al), or the like. Furthermore, the CPODE structure 111 may be formed using a suitable deposition process such as chemical vapor deposition (CVD), atomic layer deposition (ALD), physical vapor deposition (PVD), combinations of these, or the like. The CPODE structure 111 may be formed using any of the dielectric materials and processes suitable for forming the cut-metal gate structures 109. According to some embodiments, the dielectric material used to form the CPODE structure 111 is the same dielectric material used to form the cut-metal gate structures 109, although the dielectric materials may also be different. For example, in an embodiment where the cut-metal gate structures 109 are formed using silicon nitride (SiN), the CPODE structure 111 may be formed using silicon nitride (SiN) via a deposition process such as, chemical vapor deposition (CVD), atomic layer deposition (ALD), sputtering, or the like.

After depositing the dielectric material of the CPODE structure 111, the excess dielectric material outside of the opening 1003 may be removed by a chemical mechanical planarization (CMP) process. According to some embodiments, the chemical mechanical planarization (CMP) process may be continued to planarize the surfaces of the CPODE structure 111 with the gate electrode 107. After being planarized, the CPODE structure 111 over the fin 105 has a height of from about 55 nm to about 140 nm, such as about 70 nm. However, any suitable height may be used. The gate caps 801 have a height of from about 10 nm to about 30 nm, such as about 15 nm. However, any suitable height may be used. Furthermore, the cut-metal gate structures 109 have a height of from about 50 nm to about 120 nm, such as about 60 nm. However, any suitable height may be used.

In exemplary embodiments, the insulation region 111 forms an interface, such as at recessed surface 202, with the substrate 201, wherein the interface 202 includes a first trough 431 adjacent to the first fin structure 1051, a second trough 432 adjacent to the second fin structure 1052, and a raised portion 433 extending from the first trough 431 to the second trough 432.

As shown in FIG. 1, method 10 may continue, at S21, with further processing for completing the device 100. For example, the further processing may include forming interlayer dielectric and metallization layers, forming source/drain contacts to the source/drain regions, and forming source/drain vias and gate vias, in accordance with some embodiments.

Method 10 may be considered to include, at S16 through S18 and FIGS. 8-10, selectively removing the section of the metal gate lying over selected fin structure 106 to separate a first metal gate segment 1071 from a second metal gate segment 1072.

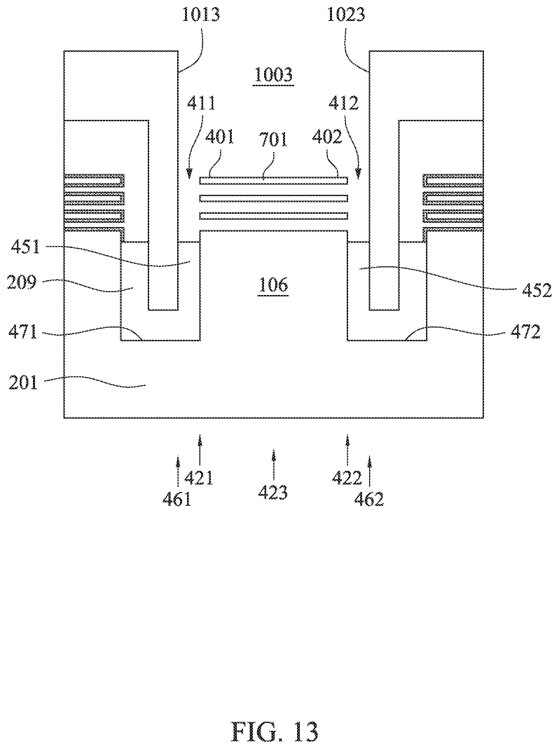

Referring now to FIG. 13, a cross-sectional view is focused on the selected fin 106 after being exposed by the removal of the gate electrode 107, such as in FIG. 10.

As shown in FIG. 13, each nanosheet 701 extends laterally from a first end 401 to a second end 402. Each first end 401 is separated from the sidewall 1013 of the opening 1003 by a gap 411. Each second end 402 is separated from the sidewall 1023 of the opening 1003 by a gap 412.

As shown, the first ends 401 are vertically positioned over a first region 421 of the semiconductor material 201, and the second ends are vertically positioned over a second region 422 of the semiconductor material 201. Further, a central region 423 of the semiconductor material 201 is located between the first region 421 and the second region 422.

As further shown, isolation 209 includes a first insulation region 451 that is located vertically under the first gap 411. In exemplary embodiments, the first region 421 of the semiconductor material 201 abuts the first insulation region 451. Likewise, isolation 209 includes a second insulation region 452 that is located vertically under the second gap 412. In exemplary embodiments, the second region 422 of the semiconductor material 201 abuts the second insulation region 452.

In FIG. 13, the semiconductor material 201 is shown to include a first outer region 461 that lies vertically under the first insulation region 451, and a second outer region 462 that lies under the second insulation region 452. As shown, the first insulation region 451 abuts the first outer region 461 at a first interface 471. Further, the second insulation region 452 abuts the second outer region 462 at a second interface 472.

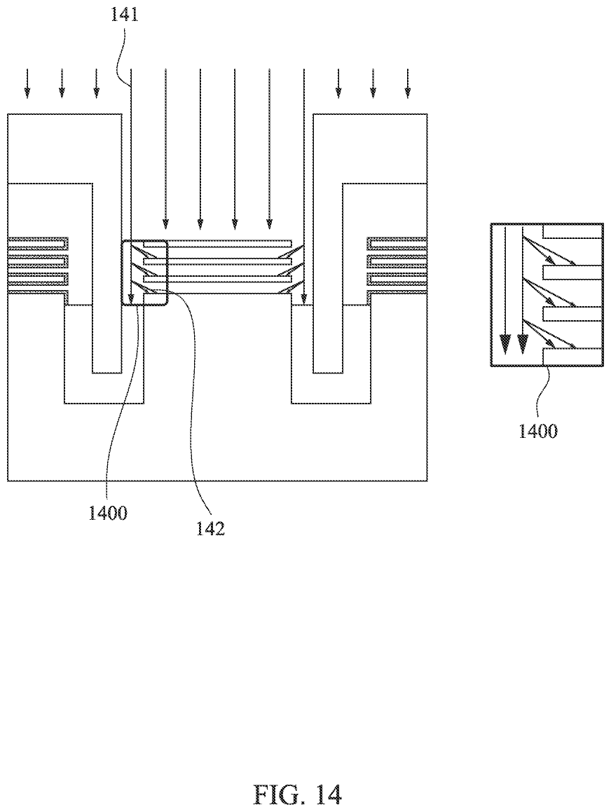

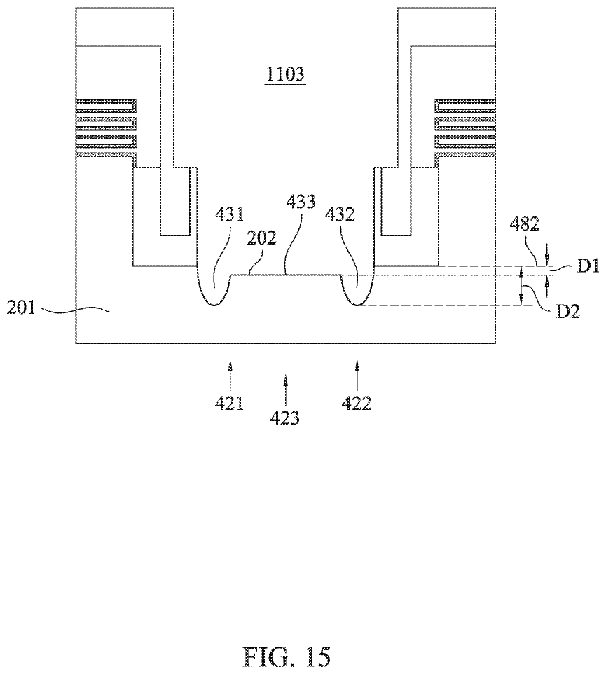

FIG. 14 illustrates the path of the etchant during the plasma etching process, such as in a vertical flow path 141 and in non-vertical flow paths 142. Box 1400 provides a close-up view of the flow paths 142 entering between nanosheets. Cross-referencing FIGS. 13 and 14, it may be seen the etchant may diffuse into the nanosheets at ends 401 and 402. Thus, the etchant may etch the ends 401 and 402 of the nanosheets 701 more quickly than the central portions of the nanosheets 701 due to the lateral flow of etchant in between nanosheets 701 as indicated by non-vertical flow paths 142. As a result, the regions 421 and 422 of the semiconductor material 201 (including fin 106) are etched sooner in the process and for a longer duration than the central region 423. Thus, more etchant may be delivered to the semiconductor material lying under the gaps 411 and 412 and ends 401 and 402, as compared to the centrally located semiconductor material. Troughs 431 and 432 as shown in FIG. 15 result from this etching process.

Referring now to FIG. 15, a cross-sectional view is focused on the opening 1103 formed by the removal of the selected fin 106 by an etching process, such as in FIG. 11. In FIG. 15, an etch process has been performed to remove the vertically-spaced nanosheets 701 and to recess the semiconductor material 201. In certain embodiments, the semiconductor material 201 includes the fin structure section 106, and the fin structure section 106 is removed when performing the etch process.

As shown, a plane 482 is defined by the interfaces 471 and 472 (labeled in FIG. 13). The central region 423 of the semiconductor material 201 is etched to a vertical depth D1 below the plane 482, and the first region 421 and the second region 422 of the semiconductor material 201 are etched to a vertical depth D2 below the plane 482. As shown, depth D2 is greater than depth D1.

Without being bound by the theory, it is believed that the plasma etch is able to etch the ends 401 and 402 of the nanosheets 701 more quickly than the central portions of the nanosheets 701. As a results, the regions 421 and 422 of the semiconductor material 201 (including fin 106) are etched sooner in the process and for a longer duration than the central region 423. Thus, more etchant may delivered to the semiconductor material lying under the gaps 411 and 412 and ends 401 and 402, as compared to the centrally located semiconductor material.

As shown, the recessed surface 202 is formed with a first trough 431, a second trough 432, and a raised portion 433 extending from the first trough 431 to the second trough 432. Alternatively, the recessed surface 202 may be considered to have a first valley 431, a second valley 432, and a mesa 433 between the first valley 431 and the second valley 432.

In exemplary embodiments, the recessed surface 202 lies below a plane 482 defined by the first interface 471 and the second interface 472. In certain embodiments, all of the recessed surface 202 lies below plane 482. In FIG. 15, at least a portion of the raised portion 433 or mesa 433 of the recessed surface 202 is distanced from the plane 482 by the depth D1. In exemplary embodiments, depth D1 is the minimum depth of the recessed surface 202. In exemplary embodiments, the maximum depth of the recessed surface 202 is depth D2 at the troughs or valleys 431 and 432.

While FIG. 15 illustrates the raised portion or mesa 433 as having a substantially planar upper surface at a constant depth, it is contemplated that minor depressions, i.e., of less depth than the depth of the troughs, may be formed therein.

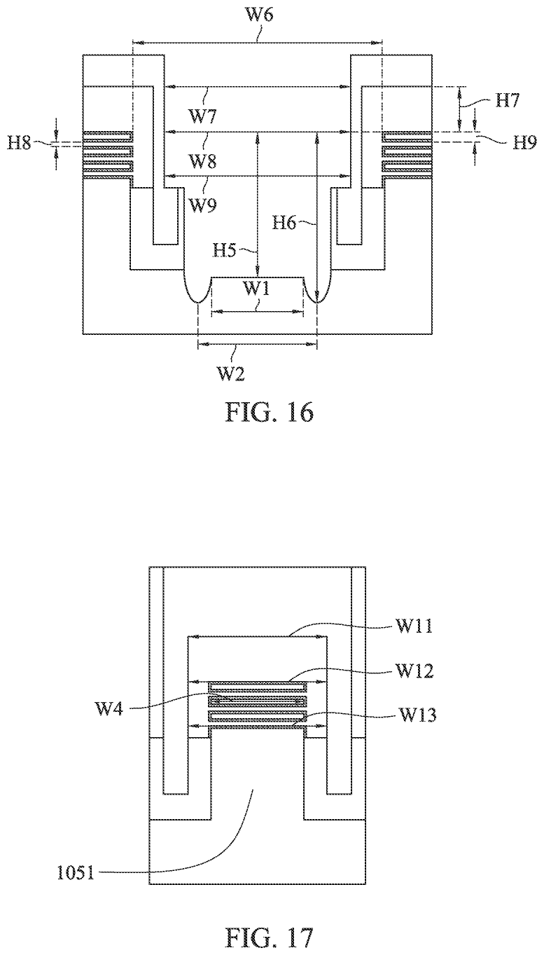

FIG. 16 provides the same image as FIG. 15, to allow for additional description of heights and widths.

As shown, a lateral width W1 extends from the first intersection of the mesa and first trough to the second intersection of the mesa and second trough. In exemplary embodiments, width W1 is from 61.9 nm to 71.3 nm, with of mean of 65.9 nm.

As shown, a lateral width W2 extends from the deepest location of the recessed surface in the first trough to the deepest location of the recessed surface in the second trough. In an exemplary embodiment, width W2 is from 104.4 nm to 106.1 nm, with a mean of 105.4 nm.

As shown, a lateral width W6 extends from the nanosheets in the first adjacent fin to the nanosheets in the second adjacent fin.

As shown, a lateral width W7 is the width of the opening at the height of the upper surface of the metal gate structure interface with the hard mask. In exemplary embodiments, the weight W7 is from 140.0 nm to 146.3 nm, with a mean of 143.2 nm.

As shown, a lateral width W8 is the width of the opening at the height of the top surface of the uppermost nanosheet. In an exemplary embodiment, the width W8 is from 147.1 nm to 152.2 nm, with a mean of 149.1 nm.

As shown, a lateral width W9 is the width of the opening at the height of the top surface of the fin structure. In an exemplary embodiment, the width W9 is from 148.0 nm to 152.6 nm, with a mean of 150.0 nm.

As shown, a vertical height H5 is the vertical distance between the top surface of the uppermost nanosheet and recessed surface in the mesa. In exemplary embodiments, the height H6 is from 141.5 nm to 144.3 nm, with a mean of 142.9 nm. As noted above, the recessed surface may not be planar. In such embodiments, a height H5 to an uppermost location on the recessed surface in the mesa is from 132.9 nm to 139.9, with a mean of 136.6 nm.

As shown, a vertical height H6 is the vertical distance between the top surface of the uppermost nanosheet and the deepest location of the recessed surface in the trough. In exemplary embodiments, the height H6 is from 151.1 nm to 157.9 nm, with a mean of 154.4 nm.

As shown, a vertical height H7 is the vertical distance between the top surface of the uppermost nanosheet and the top surface of the metal gate structure, i.e., the gate height. In exemplary embodiments, height H7 is from 20.3 nm to 21.1 nm, with a mean of 20.7 nm.

As shown, vertical height H8 is the vertical thickness of the inter-sheet metal gate portion, i.e., the vertical distance between nanosheets or sheet-sheet space. In exemplary embodiments, the height H8 is from 4.5 nm to 5.9 nm, with a mean of 5.2 nm.

As shown, vertical height H9 is the vertical thickness of a nanosheet, i.e., the sheet thickness. In an exemplary embodiment, height H9 is from 6.3 nm to 8.2 nm, with a mean of 7.1 nm.

FIG. 17 illustrates adjacent fin structure 1051 to allow for description of widths of a fin structure that remains after removing selected fin structure 106.

As shown, the metal gate structure 107 has a width W11 at an upper interface with the overlying cap or dielectric material, i.e., a top metal width. In exemplary embodiments, width W11 is from 120.5 nm to 124.2 nm, with a mean of 121.9 nm.

As shown, the metal gate structure 107 has a width W12 at the top surface of the uppermost nanosheet. In exemplary embodiments, width W12 is from 117.3 nm to 122.9 nm, with a mean of 117.3 nm.

As shown, the metal gate structure 107 has a width W13 at the top surface of the fin. In exemplary embodiments, width W13 is from 125.9 nm to 127.4 nm, with a mean of 126.7 nm.

As further shown, each nanosheet has a width W4, i.e., a sheet width. In exemplary embodiments, width W4 is from 94.9 nm to 97.5 nm, with a mean of 96.2 nm.

A method for fabricating a semiconductor device is provided and includes forming vertically-spaced nanosheets overlying a semiconductor material, wherein the vertically-spaced nanosheets extend laterally from a first end, adjacent to a first gap, to a second end, adjacent to a second gap, wherein the first end is located over a first region of the semiconductor material, wherein the second end is located over a second region of the semiconductor material, and wherein a central region of the semiconductor material is located between the first region and the second region; and performing an etch process to remove the vertically-spaced nanosheets and to recess the semiconductor material, wherein the central region of the semiconductor material is etched to a first depth, and wherein the first region and the second region of the semiconductor material are etched to depths greater than first depth.

In exemplary embodiments of the method, the etch process recesses the semiconductor material to a recessed surface, and wherein the recessed surface includes a first trough, a second trough, and a raised portion extending from the first trough to the second trough.

In exemplary embodiments of the method, the semiconductor material includes a fin structure section, and wherein the fin structure section is removed when performing the etch process.

In exemplary embodiments, the method further includes forming a metal gate over and in between the vertically-spaced nanosheets; and removing the metal gate before performing the etch process.

In exemplary embodiments of the method, the etch process forms a void, and the method further comprises depositing an insulator material in the void.

In exemplary embodiments of the method, the etch process is a plasma etch process.

In exemplary embodiments of the method, a first insulation region is located under the first gap; a second insulation region is located under the second gap; the first region of the semiconductor material abuts the first insulation region; and the second region of the semiconductor material abuts the second insulation region. In such embodiments of the method, a first outer region of the semiconductor material lies under the first insulation region; the first insulation region abuts the first outer region at a first interface; a second outer region of the semiconductor material lies under the second insulation region; the second insulation region abuts the second outer region at a second interface; the etch process recesses the semiconductor material to a recessed surface; and the recessed surface lies below a plane defined by the first interface and the second interface.

In another embodiment, a method is provided and includes forming fin structures over a substrate; forming a metal gate over the fin structures; selectively removing a section of the metal gate lying over a selected fin structure to separate a first metal gate segment from a second metal gate segment; and, after selectively removing the section of the metal gate, performing an etch process to remove a segment of the selected fin structure.

In exemplary embodiments of the method, the etch process forms a void defined by a recessed surface of the substrate, and wherein the recessed surface includes a first valley, a second valley, and a mesa between the first valley and the second valley.

In exemplary embodiments, the method further includes depositing an insulator material in the void.

In exemplary embodiments of the method, the fin structures include nanosheets; after forming the metal gate over the fin structures, inter-sheet portions of the metal gate are located between the nanosheets; and selectively removing the section of the metal gate lying over the selected fin structure comprises removing the inter-sheet portions of the metal gate over the selected fin structure.

In exemplary embodiments of the method, the selected fin structure is located between a first fin structure and a second fin structure, and wherein the method further comprises: etching the metal gate to form a first opening in the metal gate between the first fin structure and the selected fin structure and to form a second opening in the metal gate between the selected fin structure and the second fin structure; and forming a first dielectric region in the first opening and a second dielectric region in the second opening, wherein the section of the metal gate lying over the selected fin structure extends from the first dielectric region to the second dielectric region. In such embodiments, selectively removing the section of the metal gate lying over the selected fin structure comprises removing all of the metal gate between the first dielectric region and the second dielectric region.

In another embodiment, a semiconductor device is provided and includes a first fin structure located over a substrate; a first metal gate segment located over the first fin structure; a second fin structure located over the substrate; a second metal gate segment located over the second fin structure; an insulation region located between the first fin structure and the second fin structure and located between the first metal gate segment and the second metal gate segment, wherein the insulation region forms an interface with the substrate, wherein the interface includes a first trough adjacent to the first fin structure, a second trough adjacent to the second fin structure, and a raised portion extending from the first trough to the second trough.

In exemplary embodiments, the semiconductor device further includes a first shallow trench isolation region located between the first fin structure and the insulation region, wherein: the first shallow trench isolation region has a first bottom surface at a first vertical depth from a plane defined by an uppermost surface of the first fin structure; all of the interface is located at a minimum vertical depth from the plane; and the minimum vertical depth is greater than the first vertical depth.

In exemplary embodiments, the semiconductor device further comprises: a first shallow trench isolation region located between the first fin structure and the insulation region, wherein the first metal gate segment contacts the first shallow trench isolation region at a first interface; a second shallow trench isolation region located between the second fin structure and the insulation region, wherein the second metal gate segment contacts the second shallow trench isolation region at a second interface; wherein an upper portion of the insulation region contacts the first shallow trench isolation region at a first lateral interface; wherein the upper portion of the insulation region contacts the second shallow trench isolation region at a second lateral interface; and wherein the first interface, the second interface, the first lateral interface, and the second lateral interface are substantially co-planar.

In exemplary embodiments of the semiconductor device, each metal gate segment has an uppermost surface, and wherein the insulation region extends from the substrate to a height above the uppermost surface of each metal gate segment.

In exemplary embodiments of the semiconductor device, each metal gate segment has an uppermost surface, and wherein the insulation region extends from the substrate to a height above the uppermost surface of each metal gate segment.

In exemplary embodiments, the semiconductor device, further comprises: a first additional dielectric layer located between the first metal gate segment and the insulation region; and a second additional dielectric layer located between the second metal gate segment and the insulation region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
forming vertically-spaced nanosheets overlying a semiconductor material, wherein the vertically-spaced nanosheets extend laterally from a first end, adjacent to a first gap, to a second end, adjacent to a second gap, wherein the first end is located over a first region of the semiconductor material, wherein the second end is located over a second region of the semiconductor material, and wherein a central region of the semiconductor material is located between the first region and the second region; and
performing an etch process to remove the vertically-spaced nanosheets and to recess the semiconductor material, wherein the central region of the semiconductor material is etched to a first depth, and wherein the first region and the second region of the semiconductor material are etched to depths greater than first depth.

2. The method of claim 1, wherein the etch process recesses the semiconductor material to a recessed surface, and wherein the recessed surface includes a first trough, a second trough, and a raised portion extending from the first trough to the second trough.

3. The method of claim 1, wherein the semiconductor material includes a fin structure section, and wherein the fin structure section is removed when performing the etch process.

4. The method of claim 1, further comprising:
forming a metal gate over and in between the vertically-spaced nanosheets; and
removing the metal gate before performing the etch process.

5. The method of claim 1, wherein the etch process forms a void, and wherein the method further comprises depositing an insulator material in the void.

6. The method of claim 1, wherein the etch process is a plasma etch process.

7. The method of claim 1, wherein:
a first insulation region is located under the first gap;
a second insulation region is located under the second gap;
the first region of the semiconductor material abuts the first insulation region; and
the second region of the semiconductor material abuts the second insulation region.

8. The method of claim 7, wherein:
a first outer region of the semiconductor material lies under the first insulation region;
the first insulation region abuts the first outer region at a first interface;
a second outer region of the semiconductor material lies under the second insulation region;
the second insulation region abuts the second outer region at a second interface;
the etch process recesses the semiconductor material to a recessed surface; and
the recessed surface lies below a plane defined by the first interface and the second interface.

9. A method comprising:
forming fin structures over a substrate;
forming a metal gate over the fin structures;
selectively removing a section of the metal gate lying over a selected fin structure to separate a first metal gate segment from a second metal gate segment; and
after selectively removing the section of the metal gate, performing an etch process to remove a segment of the selected fin structure.

10. The method of claim 9, wherein the etch process forms a void defined by a recessed surface of the substrate, and wherein the recessed surface includes a first valley, a second valley, and a mesa between the first valley and the second valley.

11. The method of claim 10, further comprising depositing an insulator material in the void.

12. The method of claim 9, wherein:
the fin structures include nanosheets;
after forming the metal gate over the fin structures, inter-sheet portions of the metal gate are located between the nanosheets; and
selectively removing the section of the metal gate lying over the selected fin structure comprises removing the inter-sheet portions of the metal gate over the selected fin structure.

13. The method of claim 9, wherein the selected fin structure is located between a first fin structure and a second fin structure, and wherein the method further comprises:
etching the metal gate to form a first opening in the metal gate between the first fin structure and the selected fin structure and to form a second opening in the metal gate between the selected fin structure and the second fin structure; and
forming a first dielectric region in the first opening and a second dielectric region in the second opening, wherein the section of the metal gate lying over the selected fin structure extends from the first dielectric region to the second dielectric region.

14. The method of claim 13, wherein selectively removing the section of the metal gate lying over the selected fin structure comprises removing all of the metal gate between the first dielectric region and the second dielectric region.

15. A semiconductor device comprising:
a first fin structure located over a substrate;
a first metal gate segment located over the first fin structure;
a second fin structure located over the substrate;
a second metal gate segment located over the second fin structure;
an insulation region located between the first fin structure and the second fin structure and located between the first metal gate segment and the second metal gate segment, wherein the insulation region forms an interface with the substrate, wherein the interface includes a first trough adjacent to the first fin structure, a second trough adjacent to the second fin structure, and a raised portion extending from the first trough to the second trough.

16. The semiconductor device of claim 15, further comprising a first shallow trench isolation region located between the first fin structure and the insulation region, wherein:
the first shallow trench isolation region has a first bottom surface at a first vertical depth from a plane defined by an uppermost surface of the first fin structure;
all of the interface is located at a minimum vertical depth from the plane; and
the minimum vertical depth is greater than the first vertical depth.

17. The semiconductor device of claim 15, further comprising:
a first shallow trench isolation region located between the first fin structure and the insulation region, wherein the first metal gate segment contacts the first shallow trench isolation region at a first interface;
a second shallow trench isolation region located between the second fin structure and the insulation region, wherein the second metal gate segment contacts the second shallow trench isolation region at a second interface;
wherein an upper portion of the insulation region contacts the first shallow trench isolation region at a first lateral interface;
wherein the upper portion of the insulation region contacts the second shallow trench isolation region at a second lateral interface; and
wherein the first interface, the second interface, the first lateral interface, and the second lateral interface are substantially co-planar.

18. The semiconductor device of claim 15, wherein each metal gate segment has an uppermost surface, and wherein the insulation region extends from the substrate to a height above the uppermost surface of each metal gate segment.

19. The semiconductor device of claim 15, wherein each metal gate segment has an uppermost surface, and wherein the insulation region extends from the substrate to a height above the uppermost surface of each metal gate segment.

20. The semiconductor device of claim 15, further comprising:
a first additional dielectric layer located between the first metal gate segment and the insulation region; and
a second additional dielectric layer located between the second metal gate segment and the insulation region.
